(19) United States
(12) Patent Application Publication
(10) Pub. No.: US 2026/0239705 A1
(43) Pub. Date: Aug. 13, 2026

(54) MEMORY DEVICE AND FABRICATION METHOD THEREOF

(71) Applicant: NANYA TECHNOLOGY CORPORATION, New Taipei City (TW)

(72) Inventor: Wei-Chuan FANG, New Taipei City (TW)

(21) Appl. No.: 19/052,259

(22) Filed: Feb. 12, 2025

(51) Int. Cl. H10D 64/01; H01L 21/02; H01L 21/768; H10B 99/00

(52) U.S. Cl. CPC H10D 64/031; H10B 99/22; H10P 14/3411; H10P 14/6682; H10W 20/074

(57) ABSTRACT

A memory device and the fabrication method thereof are provided. The method includes forming an epitaxy layer on a first substrate region while exposing a second substrate region, forming a high-k dielectric layer on the epitaxy layer and the second substrate region, forming a first sacrificial layer on the high-k dielectric layer above the first substrate region while exposing the high-k dielectric layer above the second substrate region, forming a metal layer on the first sacrificial layer and the high-k dielectric layer, performing an annealing process to form a doping region in the high-k dielectric layer above the second substrate region, forming a gate electrode layer and a gate capping layer on the high-k dielectric layer, and patterning the gate capping layer, the gate electrode layer, and the high-k dielectric layer into gate structures above the epitaxy layer and above the doping region.

### BACKGROUND

### Field of Invention

The present disclosure relates to the memory device and the fabrication method of the memory device.

### Description of Related Art

With the advancement of semiconductor techniques, the critical dimensions (CDs) of the semiconductor components in the memory device have become smaller, which has led to an increase in the component integration in the memory device. However, as the critical dimensions of the components get smaller, the semiconductor process techniques will face many challenges. For example, since the semiconductor components of the memory device have become smaller, the device leakage relating to the gate of the memory device may occur more frequently.

### SUMMARY

According to some embodiments of the present disclosure, a method of fabricating a memory device includes the following steps. A shallow trench isolation region is formed in a substrate to divide the substrate into a first substrate region and a second substrate region. An epitaxy layer is formed on the first substrate region, where the second substrate region is exposed. A high-k dielectric layer is formed on the epitaxy layer and the second substrate region. A first sacrificial layer is formed on a first portion of the high-k dielectric layer above the first substrate region, where a second portion of the high-k dielectric layer above the second substrate region is exposed. A metal layer is formed on the first sacrificial layer and the high-k dielectric layer. An annealing process is performed to form a doping region in the high-k dielectric layer above the second substrate region. The metal layer and the first sacrificial layer are removed. A gate electrode layer is formed on the high-k dielectric layer, and a gate capping layer is formed on the gate electrode layer. The gate capping layer, the gate electrode layer, and the high-k dielectric layer are patterned into a first gate structure above the epitaxy layer and a second gate structure above the doping region.

According to some embodiments of the present disclosure, a memory device includes a first transistor having a first conductive type and a second transistor having a second conductive type different from the first conductive type. The first transistor includes a first substrate region, an epitaxy layer above the first substrate region, and a first high-k metal gate structure on the epitaxy layer. The second transistor includes a second substrate region, a doping region above the second substrate region, and a second high-k metal gate structure on the doping region. The doping region includes a high-k dielectric material doped with a metal element. The first high-k metal gate structure includes a high-k dielectric layer including the high-k dielectric material, a gate electrode layer on the high-k dielectric layer, and a gate capping layer on the gate electrode layer.

According to the above-mentioned embodiments, the method of fabricating the memory device includes forming a first sacrificial layer for the first transistor before forming the high-k metal gate structure to block the metal element of the second transistor from diffusing into the channel region of the first transistor. Therefore, the epitaxy layer in the first transistor and the doping region in the second transistor may reduce the Vₜ of operating the memory device while the high-k metal gate structure reduces the leakage in the memory device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow chart of an example method of memory device fabrication, according to some embodiments of the present disclosure.

FIGS. 2-9 illustrate schematic cross-sectional views of a memory device at various stages of fabrication, according to some embodiments of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

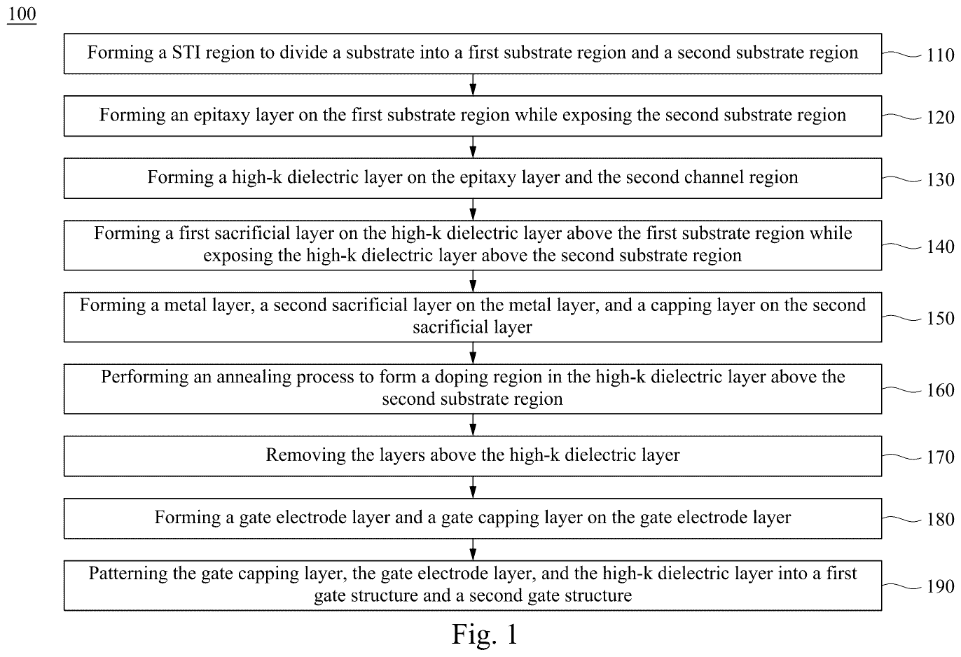

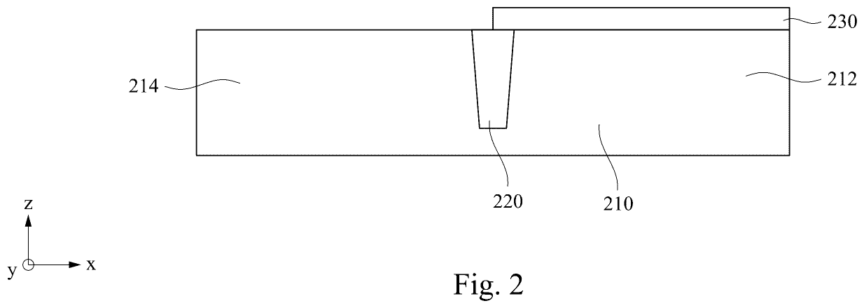

FIG. 1 illustrates a flow chart depicting an example method 100 of memory device fabrication, according to various embodiments of the present disclosure. FIG. 1 will be described in conjunction with FIGS. 2-9, which illustrate schematic cross-sectional views of a memory device 200 at various stages of fabrication, according to some embodiments of the present disclosure. The method 100 is merely an example; additional steps may be provided before, during, and after the method 100, and some of the steps described can be moved, replaced, or eliminated for additional embodiments of the method 100. Additional features may be added in the memory device 200 depicted in the figures, and some of the features described below can be replaced, modified, or eliminated in other embodiments.

At block 110, the method 100 includes forming a shallow trench isolation (STI) region in a substrate to divide the substrate into a first substrate region and a second substrate region. Referring to FIG. 2, in an embodiment of block 110, a substrate 210 is provided for forming the memory device 200. In some embodiments, the substrate 210 may be a semiconductor substrate, such as a silicon (Si) substrate. The substrate 210 may comprise a single crystalline semiconductor material such as, but not limited to Si, Ge, GaAs, InSb, GaP, GaSb, InAlAs, InGaAs, GaSbP, GaAsSb and InP. Alternatively, the substrate 102 may include a compound semiconductor and/or an alloy semiconductor.

An STI region 220 is formed in the substrate 210, where the STI region 220 extends from the top surface of the substrate 210 toward the bottom surface of the substrate 210. The bottom surface of the STI region 220 may stop in the substrate 210, as shown in FIG. 2, or the STI region 220 may penetrate through the substrate 210 in some other embodiments. The STI region 220 divides the substrate 210 into a first substrate region 212 and a second substrate region 214. In other words, the STI region 220 is interposed between the first substrate region 212 and the second substrate region 214. The first substrate region 212 and the second substrate region 214 will serve as two bases for transistors of different conductive types. For example, the first substrate region 212 may be the substrate for an n-type metal-oxide-semiconductor (NMOS) transistor of the memory device 200, while the second substrate region 214 may be the substrate for a p-type metal-oxide semiconductor (PMOS) transistor of the memory device 200.

In some embodiments, the STI region 220 may be formed of an oxide, such as SiOₓ. The STI region 220 may be formed by etching a trench in the substrate 210, followed by filling the trench with the oxide material. Although the STI region 220 in FIG. 2 is illustrated as a trapezoid with a top width at the top surface of the substrate 210 lager than a bottom width below the top surface of the substrate 210, the STI region 220 may have other shapes in some embodiments. After the formation of the STI region 220, a planarization process, such as chemical mechanical polishing (CMP), may be performed on the substrate 210 and the STI region 220 before forming other components onto the substrate 210.

At block 120, the method 100 includes forming an epitaxy layer on the first substrate region while exposing the second substrate region. Referring to FIG. 2, in an embodiment of block 120, an epitaxy layer 230 is formed on the first substrate region 212, but the epitaxy layer 230 is not formed on the second substrate region 214. As a result, the top surface of the first substrate region 212 is covered by the epitaxy layer 230 while the second substrate region 214 is exposed by the epitaxy layer 230. The epitaxy layer 230 may extend onto the top surface of the STI region 220, or the sidewall of the epitaxy layer 230 may be positioned on the top surface of the first substrate region 212. The epitaxy layer 230 may serve as the channel region between the later-formed high dielectric constant (high-k) dielectric metal gate and the first substrate region 212, where the epitaxy layer 230 reduces the threshold voltage (Vₜ) of operating a first transistor of the memory device 200.

In some embodiments which the first substrate region 212 is used for a p-type transistor, the epitaxy layer 230 may be formed of a crystalline semiconductor material such as, but not limited to SiGe. For example, a silicon-containing layer may be grown onto the first substrate region 212 by an epitaxial process or a deposition process, such as chemical vapor deposition (CVD), low-pressure chemical vapor deposition (LPCVD), atomic layer deposition (ALD), other suitable deposition process, or combinations thereof, by using a SiH₄-based gas as the precursor. The silicon-containing region is then doped by germanium (Ge) to form the epitaxy layer 230. The second substrate region 214 may be covered by a mask layer (not shown) during the deposition and/or the doping of the epitaxy layer 230. Since the epitaxy layer 230 is formed by using the SiH4-based deposition process, the resulted low surface roughness of the epitaxy layer 230 may reduce the defect in the memory device 200.

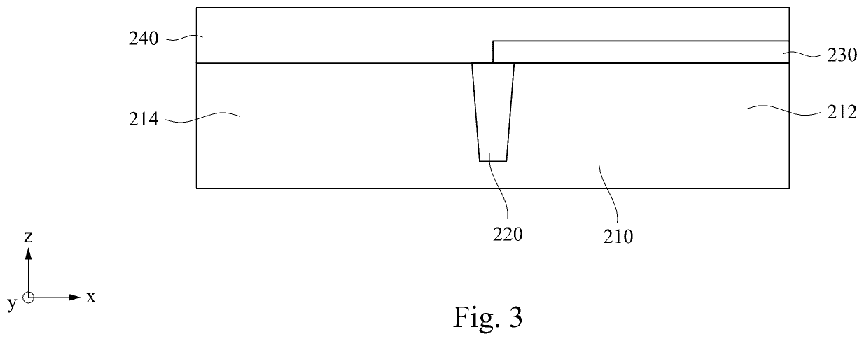

At block 130, the method 100 includes forming a high-k dielectric layer on the epitaxy layer and the second substrate region. Referring to FIG. 3, in an embodiment of block 130, a high-k dielectric layer 240 is formed on the epitaxy layer 230 and the second substrate region 214. The thickness of the high-k dielectric layer 240 along the z-axis direction is enough to cover the top surface of the epitaxy layer 230, the sidewall of the epitaxy layer 230 closer to the second substrate region 214, and the top surface of the second substrate region 214. After the formation of the high-k dielectric layer 240, a planarization process, such as chemical mechanical polishing, may be performed on the high-k dielectric layer 240 to provide the planar top surface of the high-k dielectric layer 240.

In some embodiments, the high-k dielectric layer 240 may be formed of a dielectric material having a dielectric constant (k-value) higher than that of SiO₂, such as HfO₂, HfSiOₓ, TiO₂, ZrO₂, other dielectric material having the k-value higher than 3.9, or combinations thereof. The high-k dielectric layer 240 may be formed by chemical vapor deposition, atomic layer deposition, physical vapor deposition (PVD), or other suitable deposition process.

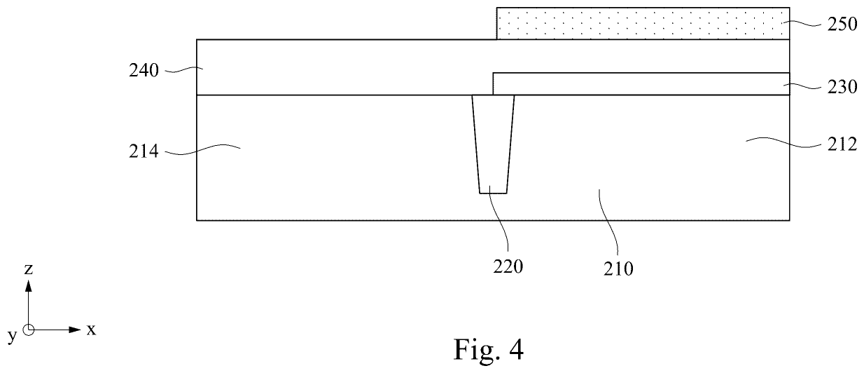

At block 140, the method 100 includes forming a first sacrificial layer on the high-k dielectric layer above the first substrate region while exposing the high-k dielectric layer above the second substrate region. Referring to FIG. 4, in an embodiment of block 140, a first sacrificial layer 250 is formed above the first substrate region 212, but the first sacrificial layer 250 is not formed above the second substrate region 214. As a result, the top surface of a first portion of the high-k dielectric layer 240 above the first substrate region 212 is covered by the first sacrificial layer 250, while the top surface of a second portion of the high-k dielectric layer 240 above the second substrate region 214 is exposed by the first sacrificial layer 250. The first sacrificial layer 250 may extend onto the top surface of the high-k dielectric layer 240 above the STI region 220. The sidewalls of the first sacrificial layer 250 may be levelled with the sidewalls of the epitaxy layer 230.

In some embodiments, the first sacrificial layer 250 may be formed of a hard mask material that can stop a metal element from penetrating into the first sacrificial layer 250 in the following process. For example, the first sacrificial layer 250 may be formed of a nitride, such as titanium nitride (TiN) or silicon nitride (SiN). The first sacrificial layer 250 may be formed by performing a deposition process on the entire top surface of the high-k dielectric layer 240 with the hard mask material, followed by removing a portion of the hard mask material above the second substrate region 214 by a wet etching process.

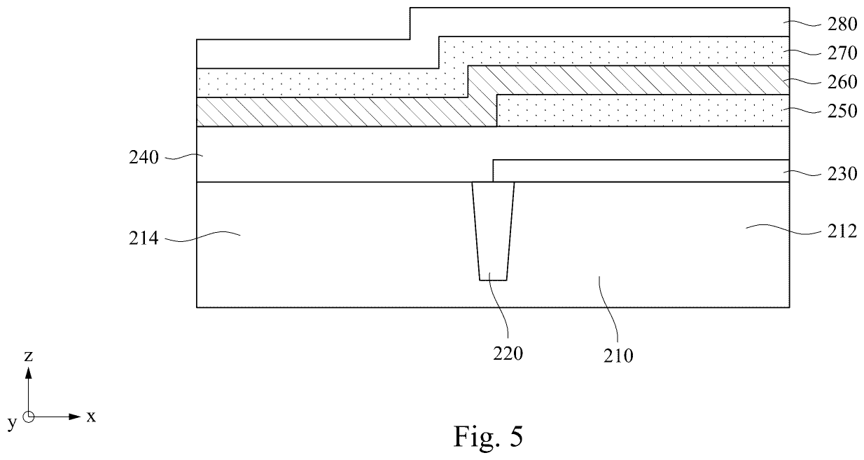

At block 150, the method 100 includes forming a metal layer on the first sacrificial layer and the high-k dielectric layer, a second sacrificial layer on the metal layer, and a capping layer on the second sacrificial layer. Referring to FIG. 5, in an embodiment of block 150, a metal layer 260 is formed above the first substrate region 212 and the second substrate region 214. The thickness of the metal layer 260 along the z-axis direction is enough to cover the top surface of the first sacrificial layer 250, the sidewall of the first sacrificial layer 250, and the top surface of the high-k dielectric layer 240 above the second substrate region 214. In some embodiments, the metal layer 260 may be formed of a metal element that will be one component of the second channel region above the second substrate region 214. For example, when the second substrate region 214 is used for an n-type transistor, the metal layer 260 may be formed of lanthanum (La). The metal layer 260 may be conformally formed by atomic layer deposition, sputtering, plating, or combinations thereof.

A second sacrificial layer 270 is formed on the metal layer 260, where the metal layer 260 is conformally covered by the second sacrificial layer 270. A capping layer 280 is then formed on the second sacrificial layer 270 to conformally cover the second sacrificial layer 270. In some embodiments, the second sacrificial layer 270 may be formed of a material same as that of the first sacrificial layer 250, so that the first sacrificial layer 250 and the second sacrificial layer 270 can stop the metal element of the metal layer 260 from penetrating into the first sacrificial layer 250 and the second sacrificial layer 270 in the following process. For example, the first sacrificial layer 250 and the second sacrificial layer 270 may both be formed of TiN layer with a thickness in a range of 1 nm to 5 nm, such as 1 nm, 2 nm, 3 nm, 4 nm, or 5 nm. The capping layer 280 may be formed of amorphous silicon. The second sacrificial layer 270 and the capping layer 280 may be formed by highly conformal deposition processes, such as atomic layer deposition.

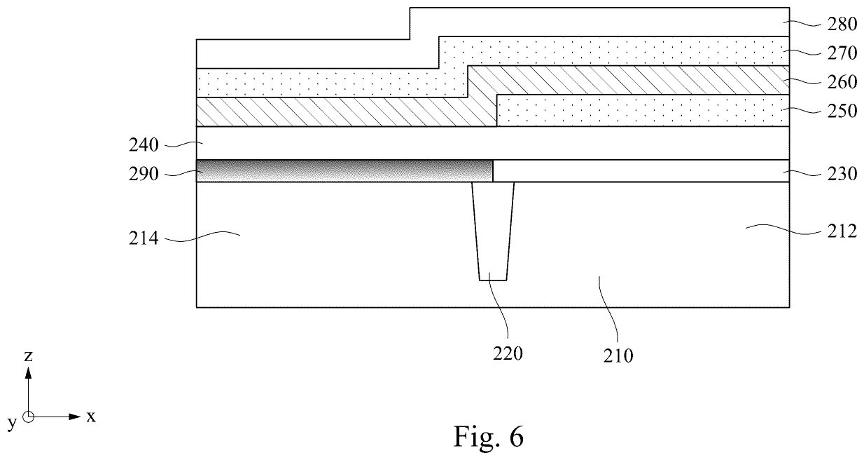

At block 160, the method 100 includes performing an annealing process to form a doping region in the high-k dielectric layer above the second substrate region. Referring to FIG. 6, in an embodiment of block 160, an annealing process is performed on the structure shown in FIG. 5. During the annealing process, the metal element of the metal layer 260 is driven into the high-k dielectric layer 240 above the second substrate region 214. As a result, a portion of the high-k dielectric layer 240 above the second substrate region 214 is doped by the metal element of the metal layer 260, which forms a doping region 290 in the high-k dielectric layer 240. The doping region 290 between the later-formed high-k dielectric metal gate and the second substrate region 214 may reduce the Vₜ of operating a second transistor of the memory device 200.

Since the high-k dielectric layer 240 above the first substrate region 212 is covered by the first sacrificial layer 250, the metal element of the metal layer 260 would not diffuse into the high-k dielectric layer 240 above the first substrate region 212. In other words, the high-k dielectric layer 240 above the first substrate region 212 and the epitaxy layer 230 are protected by the first sacrificial layer 250 during the formation of the doping region 290. This ensures the stability of the epitaxy layer 230 and the Vₜ of the corresponding transistor including the epitaxy layer 230. In addition, the second sacrificial layer 270 on the metal layer 260 may stop the metal element from diffusing toward the capping layer 280.

In some embodiments, the annealing process may be controlled to form the doping region 290 in the bottom portion of the high-k dielectric layer 240. For example, the annealing process may be performed under about 950° C. to about 1020° C. for 1 second to 5 seconds, so that the diffusion of the metal element from the metal layer 260 stops at the bottom surface of the high-k dielectric layer 240. After the annealing process, the doping region 290 may be formed between the bottom surface of the high-k dielectric layer 240 and a positon lower than or levelled with a middle positon of the high-k dielectric layer 240. The thickness of the doping region 290 along the z-axis direction may be similar to or equal to the thickness of the epitaxy layer 230. For example, the thickness of the doping region 290 may be in a range of 0.5 nm to 1.5 nm, such as 0.5 nm, 1 nm, or 1.5 nm. The sidewall of the doping region 290 closer to the first substrate region 212 may be levelled with the sidewall of the first sacrificial layer 250, or the sidewall of the doping region 290 may directly contact the sidewall of the epitaxy layer 230. A concentration of the metal element of the metal layer 260 may increase from the bottom surface of the doping region 290 toward the top surface of the doping region 290. For example, a maximum concentration of lanthanum may be at the top surface of the doping region 290, while a minimum concentration of lanthanum at the bottom surface of the doping region 290 may be close to zero.

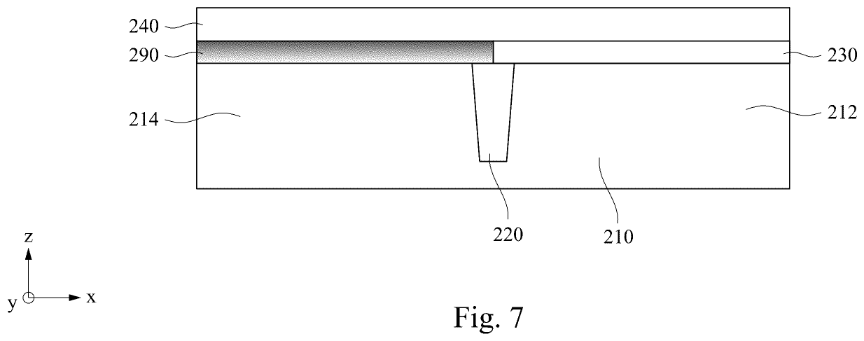

At block 170, the method 100 includes removing the layers above the high-k dielectric layer. Referring to FIG. 7, in an embodiment of block 170, an etching process is performed on the structure shown in FIG. 6 to remove the capping layer 280, the second sacrificial layer 270, the metal layer 260, and the first sacrificial layer 250. The etching process may be a multi-step wet etching process or a drying process that stop on the top surface of the high-k dielectric layer 240, so that the high-k dielectric layer 240, the doping region 290 in the high-k dielectric layer 240, and the epitaxy layer 230 basically remain un-etched during the etching process at block 170.

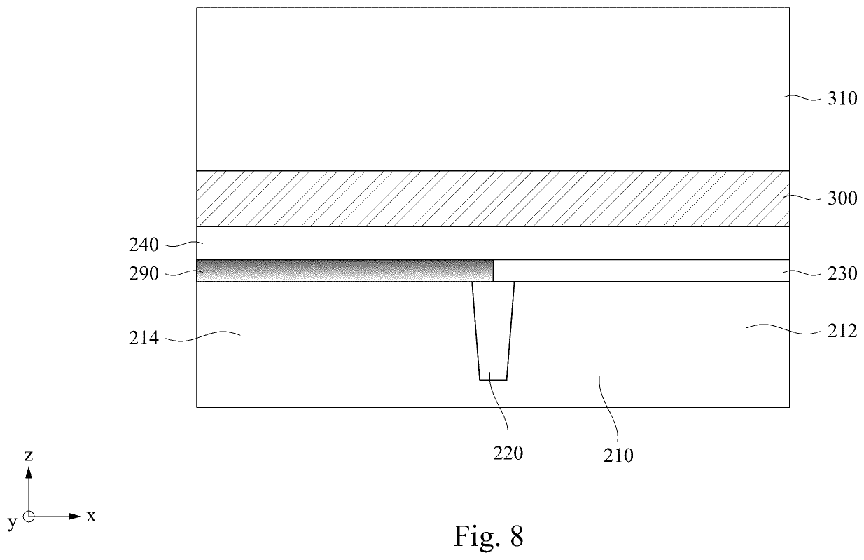

At block 180, the method 100 includes forming a gate electrode layer on the high-k dielectric layer and a gate capping layer on the gate electrode layer. Referring to FIG. 8, in an embodiment of block 180, a gate electrode layer 300 is formed on the high-k dielectric layer 240 to cover the top surface of the high-k dielectric layer 240. A gate capping layer 310 is then formed on the gate electrode layer 300. In some embodiments, the gate electrode layer 300 may be formed of a metal, a metal nitride, other conductive material, or combinations thereof, which may be formed by chemical vapor deposition, atomic layer deposition, plating, or other suitable deposition process. The gate capping layer 310 may be formed of a conductive material or a non-conductive material different from the gate electrode layer 300, which may be formed by chemical vapor deposition, atomic layer deposition, physical vapor deposition, or other suitable deposition process. For example, the gate electrode layer 300 may be formed of TiN, while the gate capping layer may be formed of polysilicon. After the formation of the gate capping layer 310, a planarization process, such as chemical mechanical polishing, may be performed on the gate capping layer 310 to provide a planar top surface of the gate stack.

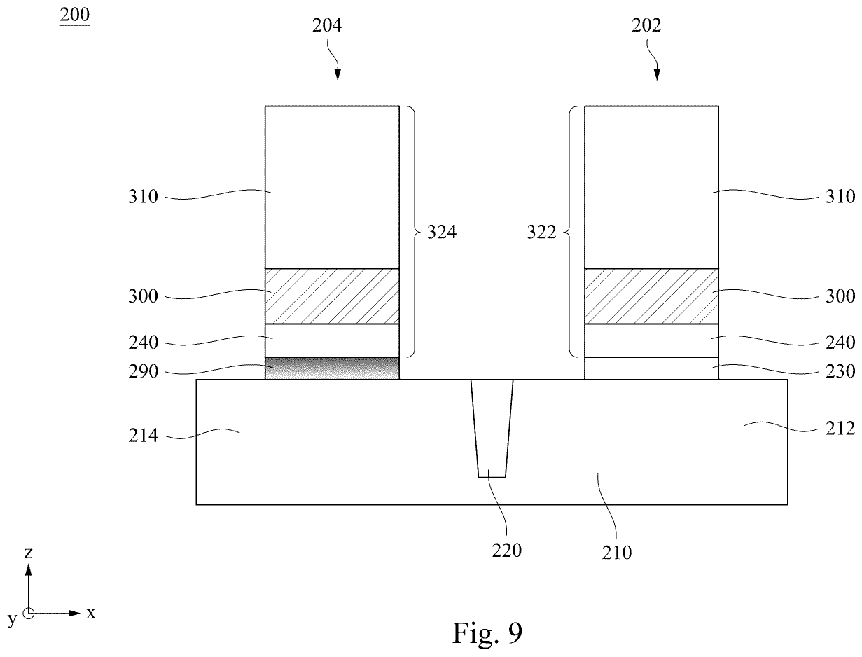

At block 190, the method 100 includes patterning the gate capping layer, the gate electrode layer, and the high-k dielectric layer into a first gate structure above the first substrate region and a second gate structure above the second substrate region. Referring to FIG. 9, in an embodiment of block 190, the gate capping layer 310, the gate electrode layer 300, and the high-k dielectric layer 240 above the first substrate region 212 are patterned into a first gate structure 322. The epitaxy layer 230 under the first gate structure 322 may also be patterned to provide the sidewalls of the epitaxy layer 230 levelled with the sidewalls of the first gate structure 322. Similarly, the gate capping layer 310, the gate electrode layer 300, and the high-k dielectric layer 240 above the second substrate region 214 are patterned into a second gate structure 324. The doping region 290 in the high-k dielectric layer 240 may also be patterned to provide the sidewalls of the doping region 290 levelled with the sidewalls of the second gate structure 324.

After the formation of the first gate structure 322 and the second gate structure 324, a first transistor 202 and a second transistor 204 separated by the STI region 220 are provided in the memory device 200. The first transistor 202 has a first conductive type, while the second transistor 204 has a second conductive type different from the first conductive type. The first transistor 202 includes the first substrate region 212, the epitaxy layer 230 above the first substrate region 212, and the first gate structure 322 on the epitaxy layer 230. The second transistor 204 includes the second substrate region 214, the doping region 290 above the second substrate region 214, and the second gate structure 324 on the doping region 290. The first gate structure 322 and the second gate structure 324 are high-k metal gate structures including the high-k dielectric layer 240, the gate electrode layer 300, and the gate capping layer 310.

In the embodiments which the first transistor 202 is a p-type transistor and the second transistor 204 is an n-type transistor, the high-k metal gate structure in any one of the first transistor 202 or the second transistor 204 may reduce the leakage relating to the high-k metal gate structure, for example, the leakage between the high-k metal gate structure and the source/drain regions. Compared to the transistor having the high-k metal gate structure directly on the substrate, the epitaxy layer 230 between the first gate structure 322 and the first substrate region 212 may reduce the Vₜ of operating the first transistor 202. Similarly, the doping region 290 doped with La between the second gate structure 324 and the second substrate region 214 may reduce the Vₜ of operating the second transistor 204. In addition, the epitaxy layer 230 formed from the SiH₄ precursor may reduce the surface roughness of the epitaxy layer 230 and the corresponding defect in the memory device 200.

According to the above-mentioned embodiments, the method of fabricating the memory device of the present disclosure includes forming a first sacrificial layer above the channel region for the first transistor to block the metal element of the second transistor from diffusing into the channel region of the first transistor. Therefore, the epitaxy layer in the first transistor and the metal doping region in the second transistor may be stable and reduce the Vₜ of operating the transistors of the memory device. The fabrication method also includes forming the high-k metal gate structures above the epitaxy layer and the doping region, which reduces the leakage in the transistors without shifting the Vₜ of operating the transistors to a value far away from 0 V.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a memory device, comprising:
forming a shallow trench isolation (STI) region in a substrate to divide the substrate into a first substrate region and a second substrate region;
forming an epitaxy layer on the first substrate region, wherein the second substrate region is exposed;
forming a high-k dielectric layer on the epitaxy layer and the second substrate region;
forming a first sacrificial layer on a first portion of the high-k dielectric layer above the first substrate region, wherein a second portion of the high-k dielectric layer above the second substrate region is exposed;
forming a metal layer on the first sacrificial layer and the high-k dielectric layer;
performing an annealing process to form a doping region in the high-k dielectric layer above the second substrate region;
removing the metal layer and the first sacrificial layer;
forming a gate electrode layer on the high-k dielectric layer and a gate capping layer on the gate electrode layer; and
patterning the gate capping layer, the gate electrode layer, and the high-k dielectric layer into a first gate structure above the epitaxy layer and a second gate structure above the doping region.

2. The method of claim 1, further comprising:
forming a second sacrificial layer to cover the metal layer;
forming a capping layer to cover the second sacrificial layer;
performing the annealing process to drive a metal element of the metal layer into the high-k dielectric layer to form the doping region; and
removing the capping layer and the second sacrificial layer after the annealing process.

3. The method of claim 2, wherein the first sacrificial layer and the second sacrificial layer are formed of a same material.

4. The method of claim 2, wherein the metal element of the metal layer stops at a bottom portion of the high-k dielectric layer after the annealing process.

5. The method of claim 1, wherein sidewalls of the first sacrificial layer are levelled with sidewalls of the epitaxy layer after forming the first sacrificial layer above the first substrate region.

6. The method of claim 1, wherein a sidewall of the doping region is levelled with a sidewall of the first sacrificial layer.

7. The method of claim 1, wherein forming the epitaxy layer on the first substrate region comprises:
epitaxial growing a silicon-containing layer by a SiH₄-based precursor on the first substrate region; and
doping the silicon-containing layer by germanium to form the epitaxy layer.

8. The method of claim 1, wherein the high-k dielectric layer covers a top surface of the epitaxy layer, a sidewall of the epitaxy layer, and a top surface of the second substrate region, and the high-k dielectric layer has a planar top surface.

9. The method of claim 1, wherein the epitaxy layer extends onto a top surface of the STI region after forming the epitaxy layer on the first substrate region.

10. The method of claim 1, wherein the metal layer and the first sacrificial layer are removed by an etching process that stops on a top surface of the high-k dielectric layer.

11. The method of claim 1, further comprising:
patterning the epitaxy layer to provide sidewalls of the epitaxy layer levelled with sidewalls of the first gate structure; and
patterning the doping region to provide sidewalls of the doping region levelled with sidewalls of the second gate structure.

12. A memory device, comprising:
a first transistor having a first conductive type, comprising:
a first substrate region;
an epitaxy layer above the first substrate region; and
a first high-k metal gate structure on the epitaxy layer; and
a second transistor having a second conductive type different from the first conductive type, comprising:
a second substrate region;
a doping region above the second substrate region, wherein the doping region comprises a high-k dielectric material doped with a metal element; and
a second high-k metal gate structure on the doping region,
wherein the first high-k metal gate structure comprises a high-k dielectric layer comprising the high-k dielectric material, a gate electrode layer on the high-k dielectric layer, and a gate capping layer on the gate electrode layer.

13. The memory device of claim 12, wherein the doping region is between a bottom surface of the high-k dielectric layer and a positon lower than or levelled with a middle positon of the high-k dielectric layer.

14. The memory device of claim 12, wherein a concentration of the metal element increases from a bottom surface of the doping region toward a top surface of the doping region.

15. The memory device of claim 12, wherein a maximum concentration of the metal element in the doping region is at a top surface of the doping region.

16. The memory device of claim 12, wherein a thickness of the doping region equals to a thickness of the epitaxy layer.

17. The memory device of claim 12, wherein the first transistor is a p-type transistor, and the second transistor is an n-type transistor.

18. The memory device of claim 12, wherein the epitaxy layer is a SiGe layer, and the doping region is the high-k dielectric material doped with lanthanum.

19. The memory device of claim 12, wherein the first high-k metal gate structure is separated from the second high-k metal gate structure, the epitaxy layer is separated from the doping region, and a shallow trench isolation region is interposed between the first substrate region and the second substrate region.

20. The memory device of claim 12, wherein the epitaxy layer serves as a channel region between the first high-k metal gate structure and the first substrate region.
